(19) United States
(12) Patent Application Publication
(10) Pub. No.: US 2015/0162281 A1
(43) Pub. Date: Jun. 11, 2015

(54) INTEGRATED CIRCUIT DEVICE AND METHOD FOR MANUFACTURING THE SAME

(71) Applicant: Kabushiki Kaisha Toshiba, Minato-ku (JP)

(72) Inventors: Yoshiko Kato, Yokohama-shi (JP); Hiromitsu Mashita, Yokohama-shi (JP)

(73) Assignee: Kabushiki Kaisha Toshiba, Minato-ku (JP)

(21) Appl. No.: 14/300,368

(22) Filed: Jun. 10, 2014

Related U.S. Application Data
(60) Provisional application No. 61/912,908, filed on Dec. 6, 2013.

(51) Int. Cl. H01L 23/528; H01L 29/417; H01L 27/115; H01L 21/311; H01L 21/768; H01L 23/522

(52) U.S. Cl. CPC H01L 23/5283; H01L 21/76802; H01L 21/76877; H01L 23/5226; H01L 27/115; H01L 21/31111; H01L 21/31144; H01L 29/4175

(57) ABSTRACT

In general, according to one embodiment, an integrated circuit device includes a first conductive member extending in a first direction, a second conductive member extending in the first direction, a first contact having a lower end connected to the first conductive member, and a second contact having a lower end connected to the second conductive member. A position of the first contact in the first direction is different from a position of the second contact in the first direction. Cross sections of the first contact and the second contact have longitudinal directions in a second direction as viewed from above. The second direction is from the first contact toward the second contact.

### CROSS-REFERENCE TO RELATED APPLICATIONS

This application is based upon and claims the benefit of priority from U.S. Provisional Patent Application 61/912,908 filed on Dec. 6, 2013; the entire contents of which are incorporated herein by reference.

### FIELD

Embodiments described herein relate generally to an integrated circuit device and a method for manufacturing the same.

### BACKGROUND

Conventionally, NAND flash memory has been developed as a nonvolatile memory device. To downscale NAND flash memory, it is effective to shorten the arrangement period of active areas formed in a silicon substrate. However, it is problematic that the formation of contacts connected to the active areas is difficult when the arrangement period of the active areas is shortened.

### BRIEF DESCRIPTION OF THE DRAWINGS

FIG. 1A to FIG. 7B are drawings showing the method for manufacturing an integrated circuit device according to a first embodiment;

FIG. 8A is a drawing showing the illumination configuration of the exposure process of the first embodiment; FIG. 8B is a drawing showing the relationship between the pattern of the mask for exposure and the opening made in a resist film; and FIG. 8C is a drawing showing the relationship between the opening of the resist film and the through-holes made in an inter-layer insulating film;

FIG. 9 is a cross-sectional view showing the integrated circuit device according to the first embodiment;

FIG. 10 is a plan view showing the positional relationships between the active areas, the openings of the resist film, and the contacts of the integrated circuit device according to the first embodiment;

FIG. 11A is a plan view showing the integrated circuit device according to the first embodiment; FIG. 11B is a plan view showing an integrated circuit device according to a first comparative example; and FIG. 11C is a plan view showing an integrated circuit device according to a second comparative example;

FIG. 12 is a plan view showing the positional relationship between the opening of the mask for exposure, the opening of the resist film, and the contacts of a first modification of the first embodiment;

FIG. 13 is a plan view showing the relationship between the opening of the resist film and the contacts of the second modification of the first embodiment;

FIG. 14 is a plan view showing the positional relationship between the active areas, the openings of the resist film, and the contacts of a second embodiment;

FIG. 15A and FIG. 15B are plan views showing the positional relationship between the active areas, the openings of the resist film, and the contacts; FIG. 15A shows the first embodiment; and FIG. 15B shows the second embodiment;

FIG. 16A is a plan view showing an integrated circuit device according to a third embodiment; and FIG. 16B is a cross-sectional view along line A-A′ shown in FIG. 16A;

FIG. 17A to FIG. 17C are drawings showing cases where the contacts above and below are shifted in a comparative example of the third embodiment;

FIG. 18A to FIG. 18C are drawings showing cases where the contacts above and below are shifted in the third embodiment;

FIG. 19A is a plan view showing an integrated circuit device according to a modification in the third embodiment; and FIG. 19B is a cross-sectional view along line A-A′ shown in FIG. 19A; and

FIG. 20 is a plan view showing an integrated circuit device according to a fourth embodiment.

### DETAILED DESCRIPTION

In general, according to one embodiment, an integrated circuit device includes a first conductive member extending in a first direction, a second conductive member extending in the first direction, a first contact having a lower end connected to the first conductive member, and a second contact having a lower end connected to the second conductive member. A position of the first contact in the first direction is different from a position of the second contact in the first direction. Cross sections of the first contact End the second contact have longitudinal directions in a second direction as viewed from above. The second direction is from the first contact toward the second contact.

In general, according to one embodiment, an integrated circuit device includes a plurality of conductive members extending in a first direction, the plurality of conductive members being arranged periodically in a second direction orthogonal to the first direction, and a plurality of contacts having lower ends connected respectively to the conductive members. A second distance is different from a first distance when the plurality of contacts is divided into a plurality of pairs including two contacts adjacent to each other. The first distance is a distance in the second direction between two of the contacts belonging to a same pair, the second distance is a distance in the second direction between two of the contacts adjacent to each other in the second direction and belonging to different pairs.

In general, according to one embodiment, a method for manufacturing an integrated circuit device, includes forming a first conductive member and a second conductive member extending in a first direction. The first conductive member and the second conductive member are separated from each other in a second direction being orthogonal to the first direction. The method includes forming an insulating film on the first conductive member and the second conductive member. The method includes forming a resist film on the insulating film. The method includes making an opening in the resist film. A longitudinal direction of the opening is a third direction intersecting both the first direction and the second direction. One end portion of the opening in the longitudinal direction is positioned above the first conductive member. One other end portion of the opening in the longitudinal direction is positioned above the second conductive member. The method includes etching the insulating film using the resist film as a mask to make a first through-hole in the insulating film under the one end portion of the opening and to make a second through-hole in the insulating film under the one other end portion of the opening. The first through-hole reaches the first conductive member. The second through-hole reaches the second conductive member. And, the method includes filling a conductive material into the first through-hole and into the second through-hole.

Embodiments of the invention will now be described with reference to the drawings.

### First Embodiment

First, a first embodiment will be described.

The integrated circuit device according to the embodiment is NAND flash memory.

A method for manufacturing the integrated circuit device according to the embodiment will now be described.

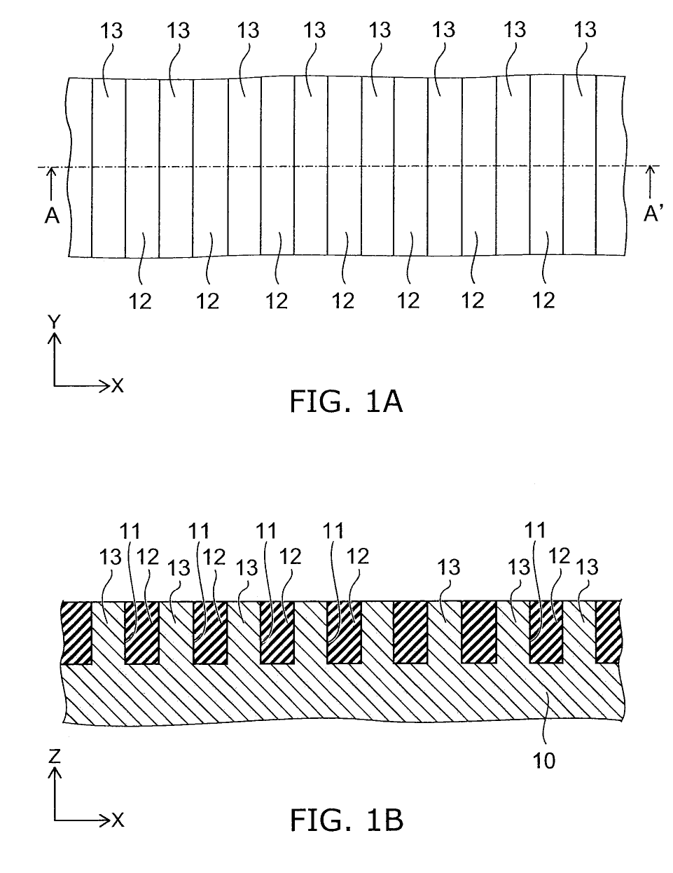

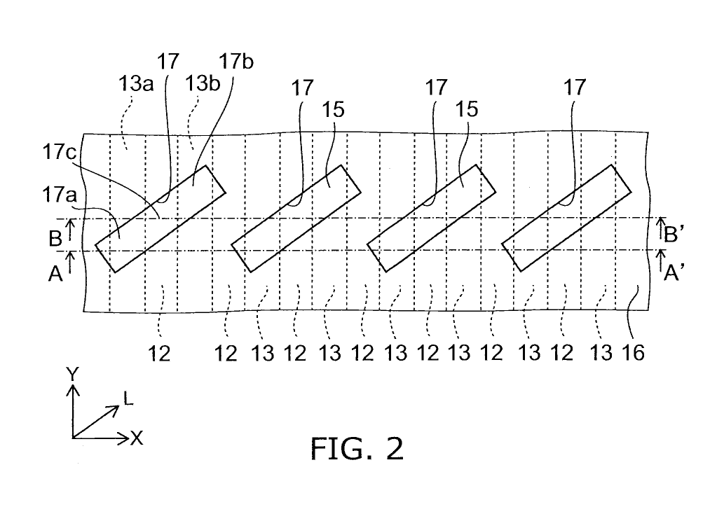

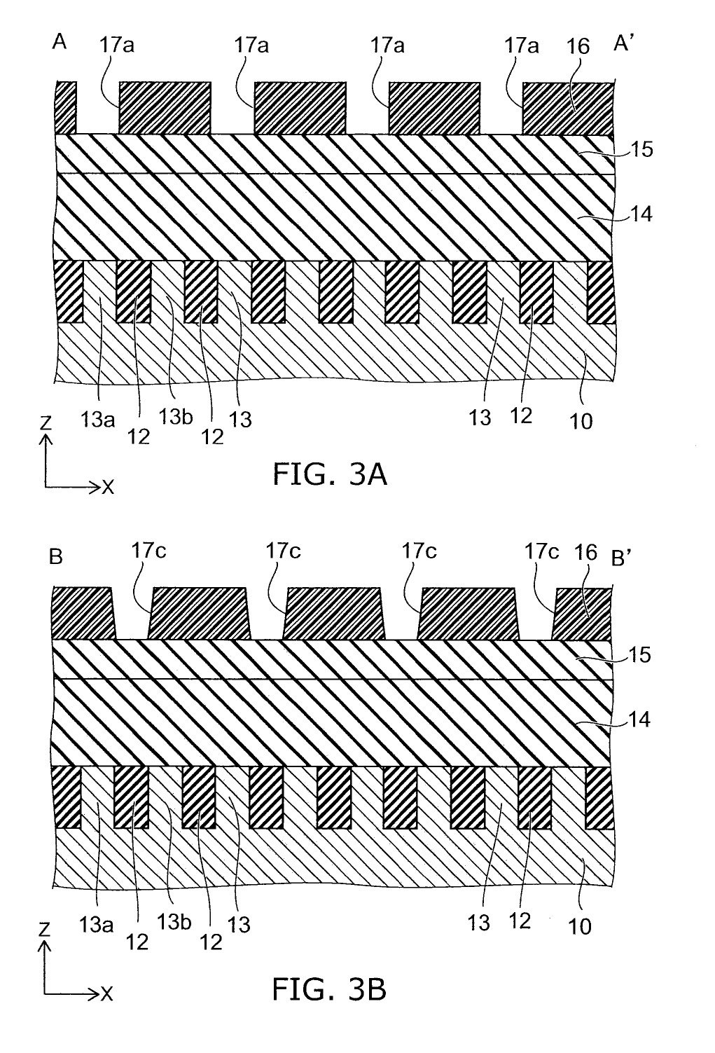

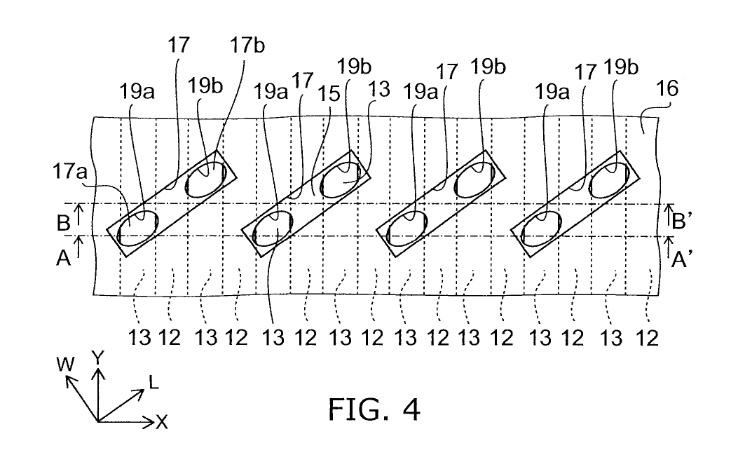

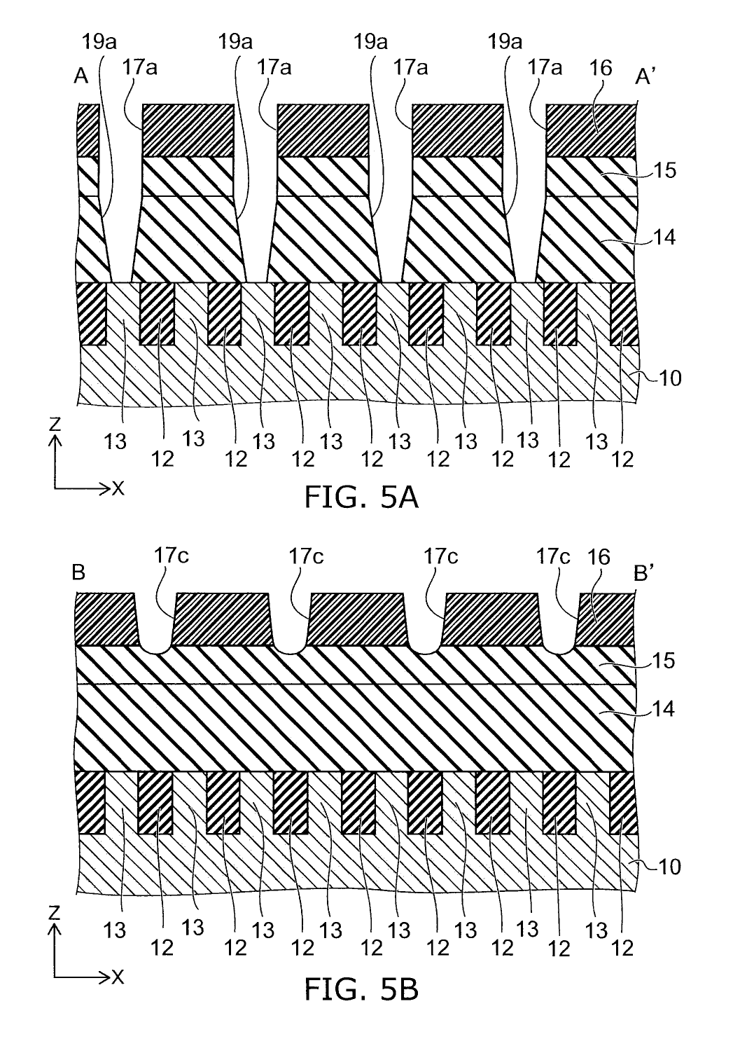

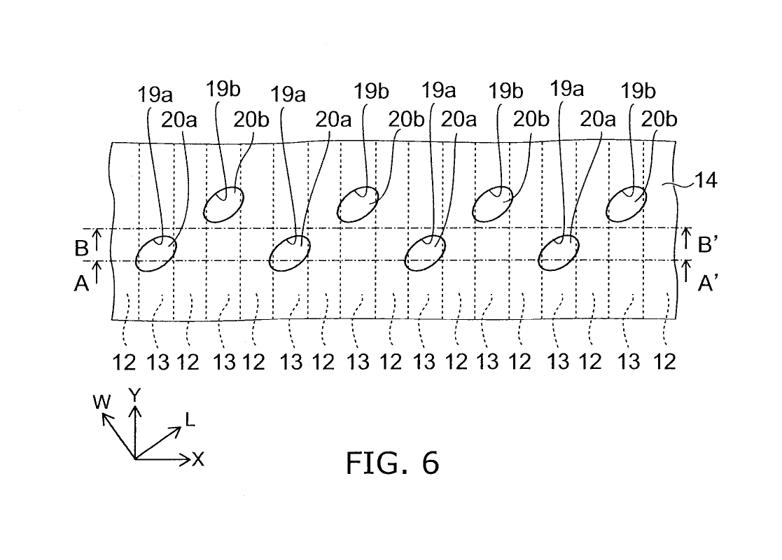

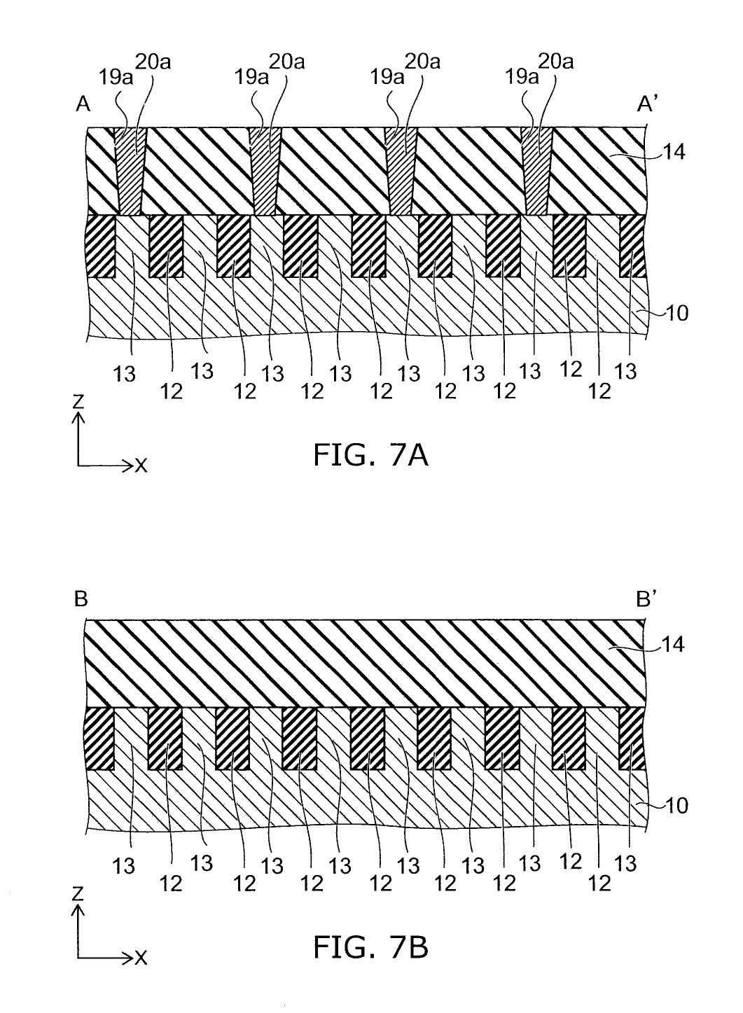

FIG. 1A to FIG. 7B are drawings showing the method for manufacturing the integrated circuit device according to the embodiment. FIG. 1A, FIG. 2, FIG. 4, and FIG. 6 are plan views; FIG. 1B, FIG. 3A, FIG. 5A, and FIG. 7A are cross-sectional views along line A-A′ shown respectively in FIG. 1A, FIG. 2, FIG. 4, and FIG. 6; and FIG. 3B, FIG. 5B, and FIG. 7B are cross-sectional views along line B-B′ shown respectively in FIG. 1A, FIG. 2, FIG. 4, and FIG. 6.

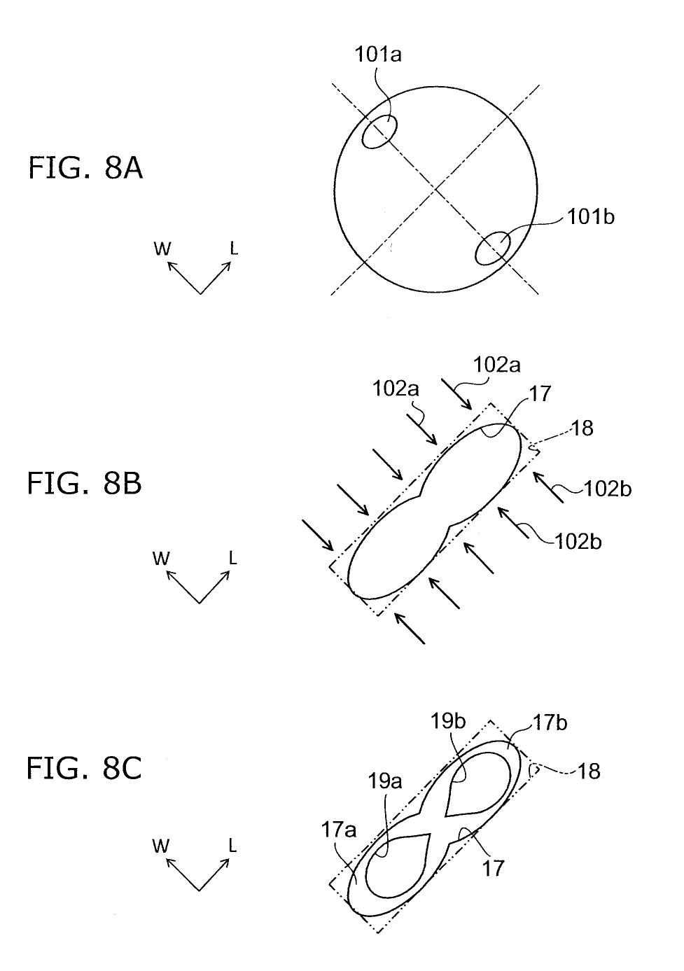

FIG. 8A is a drawing showing the illumination configuration of the exposure process of the embodiment; FIG. 8B is a drawing showing the relationship between the pattern of the mask for exposure and the opening made in the resist film; and FIG. 8C is a drawing showing the relationship between the opening of the resist film and the through-holes made in the inter-layer insulating film.

First, as shown in FIG. 1A and FIG. 1B, a silicon substrate 10 is prepared. Then, multiple trenches 11 that extend in one direction (hereinbelow, called the “Y-direction”) are made in the upper layer portion of the silicon substrate 10; and STI (Shallow Trench Isolation) 12 is filled into the trenches 11. The upper layer portion of the silicon substrate 10 is partitioned by the STI 12 into multiple active areas 13 extending in the Y-direction. The multiple active areas 13 are arranged periodically along a direction (hereinbelow, called the “X-direction”) orthogonal to the Y-direction. The active areas 13 are conductive members.

In the specification, “conductive member” refers to a solid portion through which a current can be caused to flow and includes not only interconnects, contacts, vias, etc., made of conductor materials such as metals but also semiconductor portions made of semiconductor materials such as silicon, etc. Also, in the specification, a direction orthogonal to both the X-direction and the Y-direction is called the “Z-direction.”

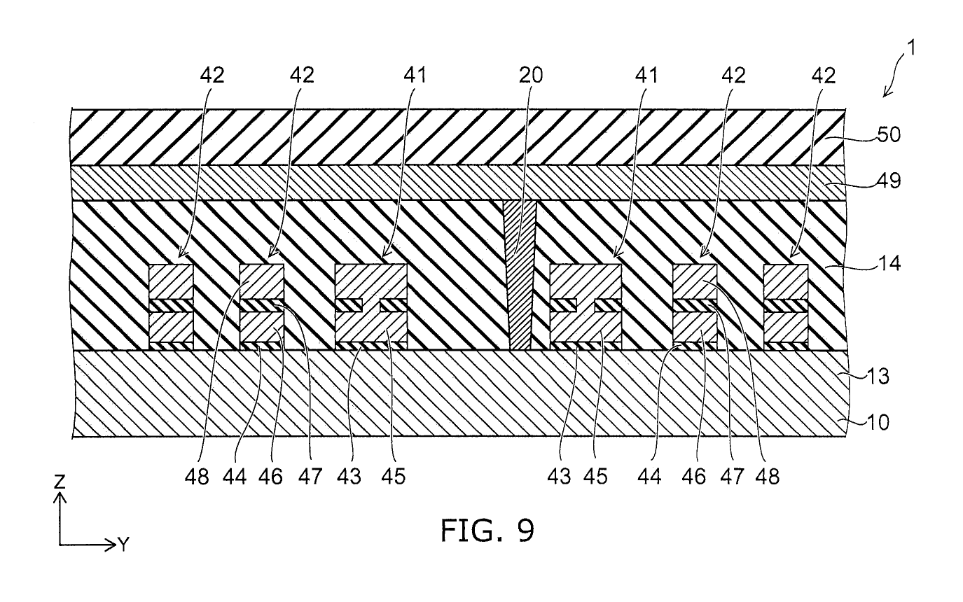

Then, a memory cell structure is made by forming a gate insulator film 43 (referring to FIG. 9), a tunneling insulating film 44 (referring to FIG. 9), a selection gate electrode 45 (referring to FIG. 9), a floating gate electrode 46 (referring to FIG. 9), an IPD 47 (Inter Poly Dielectric, referring to FIG. 9), a control gate electrode 48 (referring to FIG. 9), a source line (not shown), etc., on the silicon substrate 10 by normal methods.

Then, as shown in FIG. 2, FIG. 3A, and FIG. 3B, an inter-layer insulating film 14 is formed on the silicon substrate 10; and an insulative mask film 15 is formed on the inter-layer insulating film 14. Then, a resist film 16 is formed on the mask film 15. Then, multiple openings 17 are made by exposing and developing the resist film 1G. At this time, the positions and configurations of the openings 17 are set to have a prescribed relationship with the active areas 13.

Specifically, the cross sections of the openings 17 are set to have longitudinal directions in a direction (hereinbelow, also called the “L-direction”) intersecting both the X-direction and the Y-direction as viewed from above, i.e., from the Z-direction. Then, one end portion 17a of the opening 17 in the longitudinal direction is positioned in the region directly above one of the active areas 13 (called the “active area 13a”); and one other end portion 17b of the opening 17 in the longitudinal direction is positioned in the region directly above an active area 13 (called the “active area 13b”) disposed adjacently to the active area 13a. Then, the multiple openings 17 are arranged in one column along the X-direction; and one opening 17 is disposed every two mutually-adjacent active areas 13. The positions of the openings 17 in the Y-direction are the same.

At this time, the illumination configuration for exposure may have a constant directionality. For example, as shown in FIG. 8A and FIG. 8B, among the patterns formed in the mask for exposure, a pattern 18 for forming the opening 17 may be set to be a rectangle having the longitudinal direction in a direction that is optically equivalent to the L-direction; and the illumination may be a dipole illumination having a high NA value. Specifically, light sources 101a and 101b may be disposed to be separated in a direction that is optically equivalent to a direction (hereinbelow, called the “W-direction”) orthogonal to the L-direction. Thereby, light 102a and 102b is irradiated onto the pattern 18 of the mask for exposure from the two sides in the direction corresponding to the W-direction; and the light 102a and 102b is irradiated from the two sides in the W-direction onto the region of the resist film 16 where the opening 17 is to be made. The configuration of the pattern 18 may be set to be an ellipse. Then, the resist film 16 is developed.

As a result, an opening that has a configuration having a longitudinal direction in the L-direction is made in the resist film 16. For example, the configuration of the opening 17 is a gourd shape having a pinched-in longitudinal-direction central portion. In other words, as shown in FIG. 3A, the resist film 16 has a complete opening at the end portions 17a and 17b of the opening 17. On the other hand, at a central portion 17c of the opening 17 as shown in FIG. 3B, the resist film 16 has an opening; but the opening is insufficient. In FIG. 3A and FIG. 5A, the configuration of the opening 17 is shown as a rectangle for convenience of illustration. This is similar for subsequent plan views as well.

Then, as shown in FIG. 4, FIG. 5A, and FIG. 5B, anisotropic etching such as, for example, RIE (Reactive Ion Etching), etc., is performed using the resist film 16 as a mask. Thereby, in the regions directly under the end portions 17a and 17b of the opening 17 as shown in FIG. 5A, there are openings in the mask film 15; holes having tapers are made in the inter-layer insulating film 14; and through-holes that reach the active areas 13 are made. On the other hand, in the region directly under the central portion 17c or the opening 17 as shown in FIG. 5B, a recess is made in the mask film 15 but the mask film 15 is not pierced; and accordingly, a through-hole is not made in the inter-layer insulating film 14. Therefore, the through-holes are made not in the entire region directly under the opening 17 but at the two end portions of the opening 17 in the longitudinal direction (the L-direction). In other words, a through-hole 19a is made in the region directly under the one longitudinal-direction end portion 17a of the opening 17; and a through-hole 19b is made in the region directly under the one other longitudinal-direction end portion 17b of the opening 17. 1 he through-hole 19a and the through-hole 19b are separated from each other and respectively reach two mutually-adjacent active areas 13. On the other hand, a through-hole that reaches the STI 12 is not made in the region directly under the longitudinal-direction central portion 17c of the opening 17.

At this time, there are many cases where the configurations of the through-holes 19a and 19b are configurations having longitudinal directions in the L-direction. For example, there are cases where the configurations of the through-holes 19a and 19b are water drop shapes. A “water drop shape” is an ellipse or a shape that is nearly an ellipse and has one sharp end portion in the major-diameter direction. Specifically, there are cases where the configuration of the through-hole 19a is a water drop shape having a sharp end portion on the through-hole 19b side as viewed from the Z-direction, and the configuration of the through-hole 19b is a water drop shape having a sharp end portion on the through-hole 19a side as viewed from the Z-direction.

Then, as shown in FIG. 6, FIG. 7A, and FIG. 7B, the resist film 16 and the mask film 15 are removed; and a conductive material such as tungsten, etc., is filled into the through-holes 19a and 19b. Thereby, a contact 20a is formed inside the through-hole 19a; and a contact 20b is formed inside the through-hole 19b. The lower ends of the contacts 20a and 20b (hereinbelow, also generally called the “contact 20”) are connected to the upper surfaces of the active areas 13.

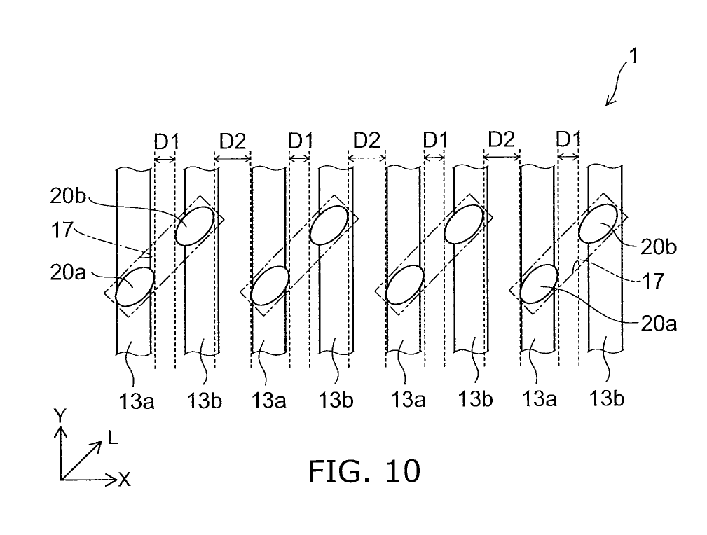

Then, bit lines 49 (referring to FIG. 9), an inter-layer insulating film 50 (referring to FIG. 10), etc., are formed by normal methods. The bit lines 49 are connected to the upper ends of the contacts 20. Thereby, the integrated circuit device 1 according to the embodiment is manufactured.

The configuration of the integrated circuit device after completion will now be described.

FIG. 9 is a cross-sectional view showing the integrated circuit device according to the embodiment.

FIG. 10 is a plan view showing the positional relationships between the active areas, the openings of the resist film, and the contacts of the integrated circuit device according to the embodiment.

In FIG. 10, only the active areas 13a and 13b, the openings 17, and the contacts 20a and 20b are shown for easier viewing or the drawing. This is similar for subsequent drawings that are similar.

In the integrated circuit device 1 according to the embodiment as shown in FIG. 6, FIG. 7A, FIG. 7B, FIG. 9, and FIG. 10, the silicon substrate 10 is provided; and the multiple STIs 12 that extend in the Y-direction are provided in the upper surface of the silicon substrate 10. The upper layer portion of the silicon substrate 10 is partitioned by the STIs 12 into the multiple active areas 13 extending in the Y-direction. As described above, the “active area 13” also is called the “active area 13a” and the “active area 13b.” The active area 13a and the active area 13b are arranged alternately along the X-direction.

The inter-layer insulating film 14 and the mask film 15 are provided on the silicon substrate 10 and the STIs 12. The contacts 20a and 20b are filled into the inter-layer insulating film 14 and the mask film 15 to pierce the inter-layer insulating film 14 and the mask film 15 in the Z-direction. The lower end of the contact 20a is connected to the active area 13a; and the lower end of the contact 20b is connected to the active area 13b. The contact 20a and the contact 20b are arranged alternately along the X-direction. Also, the position of the contact 20a is different from the position of the contact 20b in the Y-direction.

Also, the contacts 20a and 20b have configurations having longitudinal directions in the L-direction as viewed from above, i.e., from the Z-direction. The L-direction intersects the X-direction and the Y-direction and is the direction from the contact 20a toward the contact 20b for the contact 20a and the contact 20b that are formed inside the same opening 17. For example, the configuration of the contact 20a is a water drop shape having a sharp end portion on the contact 20b side as viewed from the Z-direction; and the configuration of the contact 20b is a water drop shape having a sharp end portion on the contact 20a side as viewed from the Z-direction,

On the other hand, the space between the contact 20a and the contact 20b is filled with the inter-layer insulating film 14 and the mask film 15; and the contacts are not formed in the regions directly above the STIs 12.

Also, as shown in FIG. 10, a distance D1 is the distance in the X-direction between the contact 20a and the contact 20b formed inside the same opening 17. Also, a distance D2 is the distance in the X-direction between the contact 20a and the contact 20b that are adjacent to each other in the X-direction and formed inside different openings 17. Generally, the distance D2 is different from the distance D1.

As shown in FIG. 9, a pair of selection gate stacked bodies 41 are provided at positions on two sides of the contact 20 on the silicon substrate 10; and multiple control gate stacked bodies 42 are provided on the outer sides of the pair of selection gate stacked bodies 41. The selection gate stacked bodies 41 and the control gate stacked bodies 42 extend in the X-direction. The gate insulator film 43 and the selection gate electrode 45 are stacked in order from the lower layer side in each of the selection gate stacked bodies 41. The tunneling insulating film 44, the floating gate electrode 46, the IPD 47, and the control gate electrode 48 are stacked in order from the lower layer side in each of the control gate stacked bodies 42, The floating gate electrode 46 is divided every active area 13 along the X-direction. Also, a source line (not shown) that extends in the X-direction is provided on the silicon substrate 10 to be commonly connected to the multiple active areas 13. The source line, the selection gate stacked bodies 41, and the control gate stacked bodies 42 are covered with the inter-layer insulating film 14.

The multiple bit lines 49 are provided on the mask film 15. The bit lines 49 are disposed in the regions directly above the active areas 13 and extend in the Y-direction. The bit lines 49 are connected to the upper end portions of the contacts 20. The inter-layer insulating film 50 is provided to cover the bit lines 49.

Effects of the embodiment will now be described.

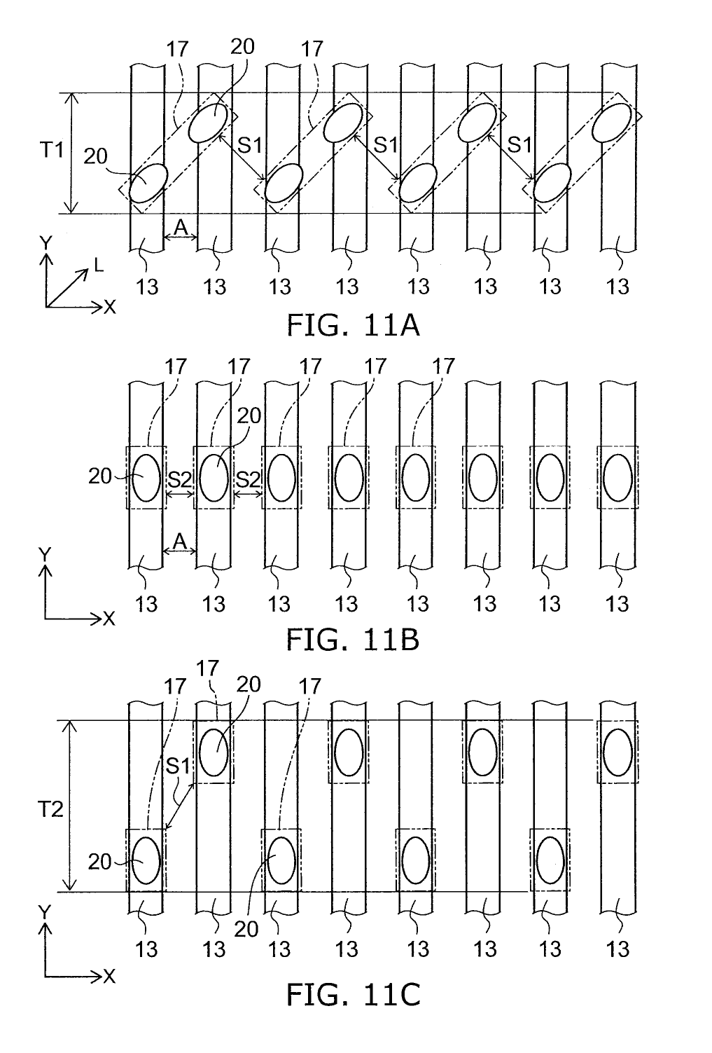

FIG. 11A is a plan view showing the integrated circuit device according to the embodiment; FIG. 11B is a plan view showing an integrated circuit device according to a first comparative example;

and FIG. 11C is a plan view showing an integrated circuit device according to a second comparative example. In FIG. 11A to FIG. 11C, only the active areas 13, the openings 17, and the contacts 20 are shown for easier viewing of the drawings.

In the embodiment as shown in FIG. 11A, when forming the contacts 20 connected to the active areas 13, a distance S1 between the openings 17 made in the resist film 16 (referring to FIG. 3A) can be greater than a distance A between the active areas 13. Thereby, the lithography for making the openings 17 can be performed easily. In other words, higher integration of the integrated circuit device 1 can be realized by shortening the distance A between the active areas 13 while setting the distance S1 between the openings 17 to be a constant value within the constraints of available lithography technology.

Conversely, as shown in FIG. 11B, in the case where one contact 20 is formed in one opening 17, a distance S2 between the openings 17 is about the same as the distance A between the active areas 13 and is undesirably shorter than the distance S1. As a result, the lithography for making the openings 17 is difficult. On the other hand, as shown in FIG. 11C, it may be considered to ensure the distance S1 between the openings 17 by disposing the openings 17 in a staggered configuration. However, in such a case, a length T2 in the Y-direction of the contact format:on region is undesirably longer than a length T1 in the Y-direction of the contact formation region of the embodiment. Thereby, higher integration of the integrated circuit device is obstructed.

### First Modification of First Embodiment

A first modification of the first embodiment will now be described.

FIG. 12 is a plan view showing the positional relationship between the opening of the mask for exposure, the opening of the resist film, and the contacts of the modification.

In the modification as shown in FIG. 12, the outer edge of the opening 17 made in the resist film 16 juts from a rectangle optically equivalent to the outer edge of the pattern 18 of the mask for exposure at two end portions in the longitudinal direction (the L-direction) of the opening 17. There are cases where the pattern 18 and the opening 17 have such a relationship due to the conditions of the exposure and development. Otherwise, the manufacturing method, the configuration, and the effects of the modification are similar to those of the first embodiment described above.

### Second Modification of First Embodiment

A second modification of the first embodiment will now be described.

FIG. 13 is a plan view showing the relationship between the opening of the resist film and the contacts of the modification.

In the modification as shown in FIG. 13, the configurations of the contacts 20 are ellipses having major diameters extending in the L-direction as viewed from the Z-direction. There are cases where the configurations of the contacts 20 are not water drop shapes but are elliptical shapes due to the conditions of the exposure, development, and etching. Otherwise, the manufacturing method, the configuration, and the effects of the modification are similar to those of the first embodiment described above.

### Second Embodiment

A second embodiment will now be described.

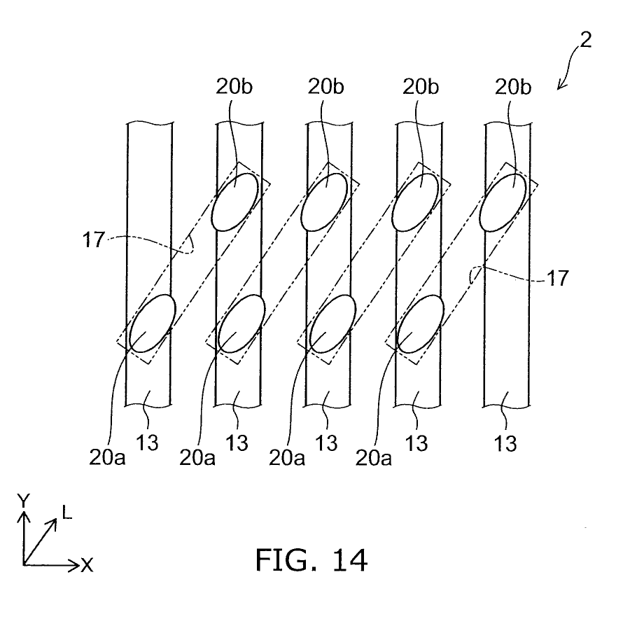

FIG. 14 is a plan view showing the positional relationship between the active areas, the openings of the resist film, and the contacts of the embodiment.

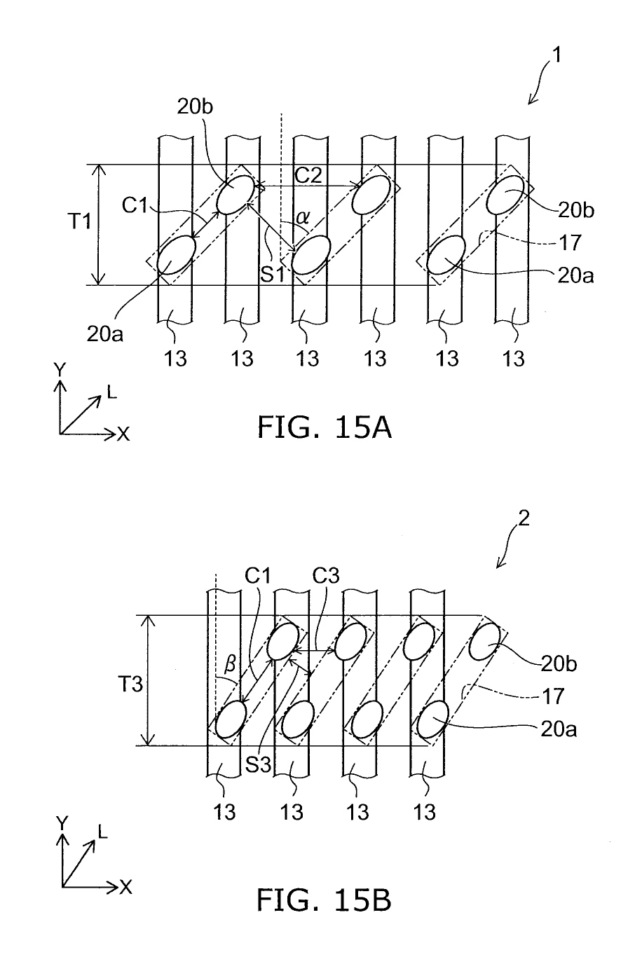

FIG. 15A and FIG. 15B are plan views showing the positional relationship between the active areas, the openings of the resist film, and the contacts; FIG. 15A shows the first embodiment; and FIG. 15B shows the second embodiment.

In the integrated circuit device 2 according to the embodiment as shown in FIG. 14, the contact 20a formed inside one opening 17 and the contact 20b formed inside the opening 17 adjacent to the one opening 17 are connected to each of the active areas 13. In other words, the two contacts 20a and 20b are connected to one of the active areas 13.

In the embodiment as shown in FIG. 15A and FIG. 15E, an angle β between the Y-direction and the longitudinal direction (the L-direction) of the opening 17 is smaller than an angle α of the first embodiment described above. Thereby, a distance S3 between the openings 17 can be prevented from being too short while arranging the openings 17 at the same arrangement period as the active areas 13. By ensuring the distance S3, the lithography of the openings 17 can be prevented from becoming difficult. However, a length 12 in the Y-direction of the contact formation region increases as the angle β decreases. Therefore, the angle β is determined by considering the trade-off between the ease of the lithography and higher integration of the integrated circuit device.

Also, to ensure a distance C3 between the contacts 20a and between the contacts 20b, it is favorable for the minor diameters of the contacts 20a and 20b to be shorter than those of the first embodiment. By increasing the distance C3, the breakdown voltage between the contacts 20a connected to different active areas 13 and the breakdown voltage between the contacts 20b connected to different active areas 13 can be ensured.

Effects of the embodiment will now be described.

According to the embodiment, because the active area 13 and the bit line (not shown) are connected to each other via two contacts, the resistance between the active area 13 and the bit line can be reduced.

Otherwise, the manufacturing method, the configuration, and the effects of the embodiment are similar to those of the first embodiment described above.

### Third Embodiment

A third embodiment will now be described.

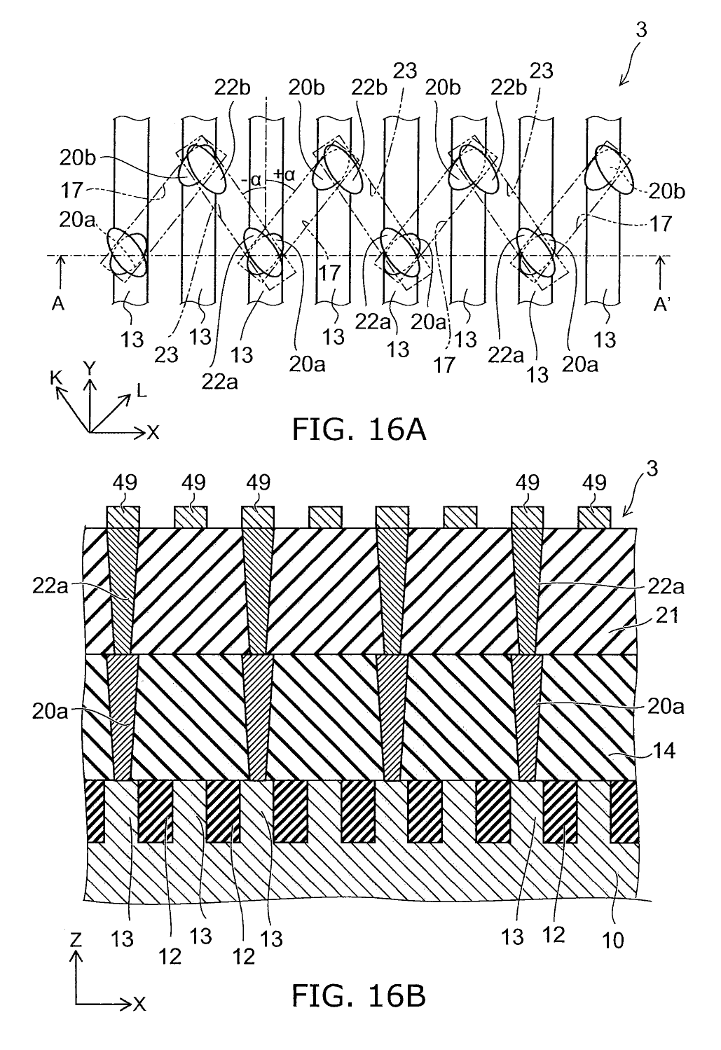

FIG. 16A is a plan view showing an integrated circuit device according to the embodiment; and FIG. 16B is a cross-sectional view along line A-A′ shown in FIG. 16A.

In the integrated circuit device 3 according to the embodiment as shown in FIG. 16A and FIG. 16B, an inter-layer insulating film 21 is provided on the mask film 15. Vias 22a and 22b are provided inside the inter-layer insulating film 21 to pierce the inter-layer insulating film 21 in the Z-direction. When viewed from the Z-direction, the position of the via 22a is substantially the same as the position of the contact 20a; and the position of the via 22b is substantially the same as the position of the contact 20b. Accordingly, in the Y-direction, the position of the via 22b is different from the position of the via 22a. Also, the lower end of the via 22a is connected to the upper end of the contact 20a; and the lower end of the via 22b is connected to the upper end of the contact 200. The upper ends of the vias 22a and 22b are connected to the bit lines 09. In FIG. 16A, the bit lines 49 are not shown for convenience of illustration.

The method for forming the vias 22a and 22b is similar to the method for forming the contacts 20a and 20b. Namely, a mask film (not shown) is formed on the inter-layer insulating film 21; a resist film (not shown) is formed on the mask film; rectangular openings 23 are made in the resist film; and subsequently, one via 22a and one via 22b are formed inside each of the openings 23 by etching using the resist film as a mask.

However, the longitudinal direction of the opening 23 is different from the major-axis direction of the opening 17. When the angle at which the major-axis direction (the L-direction) of the opening 17 is tilted with respect to the Y-direction is taken to be (+α), the angle at which the major-axis direction (hereinbelow, called the “K-direction”) of the opening 23 is tilted with respect to the Y-direction becomes (−α). In other words, the opening 23 is e mirror image of the opening 17 around the YZ plane including the central axis of the active area 13. Therefore, the opening 23 and the opening 17 do not correspond one-to-one. In other words, the contacts 20a and 20b that are connected respectively to the vias 22a and 22b formed inside one opening 23 are formed inside mutually-different openings 17. Conversely, the vias 22a and 22b that are connected respectively to the contacts 20a and 20b formed inside one opening 17 are formed inside mutually-different openings 23.

Accordingly, as viewed from the Z-direction, the longitudinal directions of the vias 22a and 22b are the L-direction; but the longitudinal directions of the contacts 20a and 20b are the K-direction. For example, for the vias 22a and 22b formed inside one opening 23, the configuration of the via 22a is an elliptical shape or a water drop shape having a sharp end portion on the via 22b and the configuration of the via 22b is an elliptical shape or a water drop shape having a sharp end portion on the via 22a side.

Effects of the embodiment will now be described.

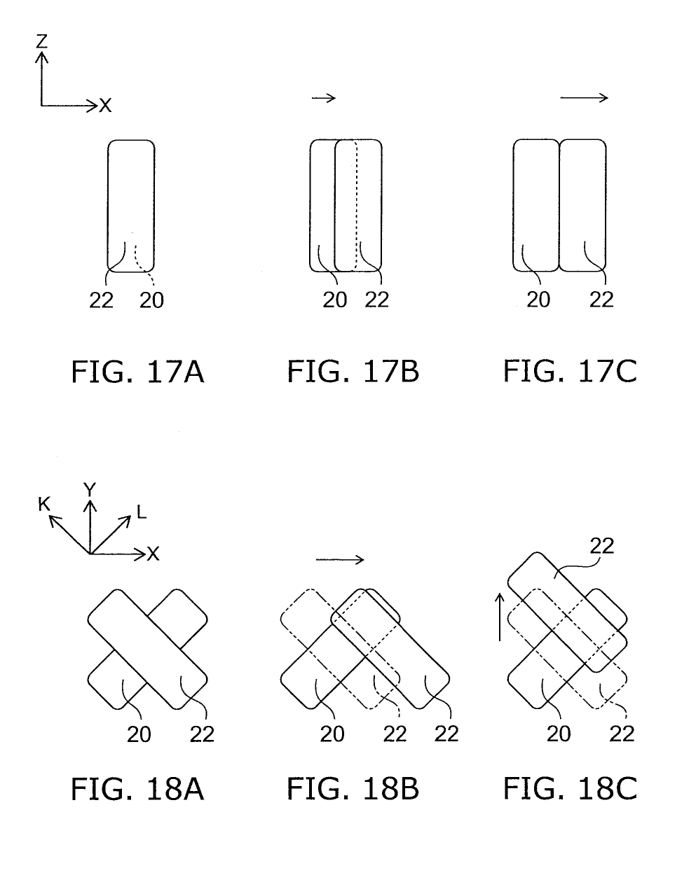

FIG. 17A to FIG. 17C are drawings showing cases where the contacts above and below are shifted in a comparative example.

FIG. 18A to FIG. 18C are drawings showing cases where the contacts above and below are shifted in the embodiment.

In FIG. 17A to FIG. 18C, the XY cross-sectional configurations of the contacts are taken to be constant regardless of the position in the Z-direction for convenience of illustration.

In the comparative example as shown in FIG. 17A to FIG. 17C, the longitudinal direction of the contact 20 on the lower side and the longitudinal direction of the via 22 on the upper side match and are the Y-direction. As shown in FIG. 17A, in the case where the shift amount in the lateral direction (the X-direction) between the contacts above and below is zero, the contact surface area between the contacts above and below is equal to the surface area of the upper surface of the contact 20 and the surface area of the lower surface of the via 22. This surface area is taken to be “1.” However, as shown in FIG. 17B, in the case where the shift amount between the contacts is half of the minor diameter of the contact, the contact surface area between the contacts above and below undesirably becomes “0.5.” Then, as shown in FIG. 17C, in the case where the shift amount between the contacts is equal to the minor diameter of the contact, the contact surface area between the contacts above and below becomes “0” and a break undesirably occurs. Thus, for the device according to the comparative example, the tolerance for the positional shift in the lateral direction of the contacts above and below is low; and the manufacturing is difficult.

In the embodiment as shown in FIG. 18A to FIG. 18C, the longitudinal direction (the L-direction) of the contact 20 on the lower side and the longitudinal direction (the K-direction) of the via 22 on the upper side intersect each other. As shown in FIG. 18A, the contact surface area between the contacts above and below is taken to be “1” in the case where the shift amount between the contacts above and below is zero. As shown in FIG. 18B, even in the case where the via 22 shifts from the contact 20 in the X-direction, the contact surface area is still “1” if the shift amount is not more than a constant value. Also, as shown in FIG. 18C, even in the case where the via 22 shifts from the contact 20 in the Y-direction, the contact surface area is still “1” if the shift amount is not more than a constant value. Thus, in the embodiment, if the shift amount between the contacts above and below is not more than a constant value, the decrease of the contact surface area can be prevented even for shifting in either direction. Therefore, for the integrated circuit device 3 according to the embodiment, the tolerance relating to the positional shift between the contacts above and below is high; and the manufacturing stability is high. Accordingly, a product having good characteristics can be manufactured stably even when the integrated circuit device is downscaled.

Otherwise, the manufacturing method, the configuration, and the effects of the embodiment are similar to those of the first embodiment described above.

### Modification of Third Embodiment

A modification of the third embodiment will now be described.

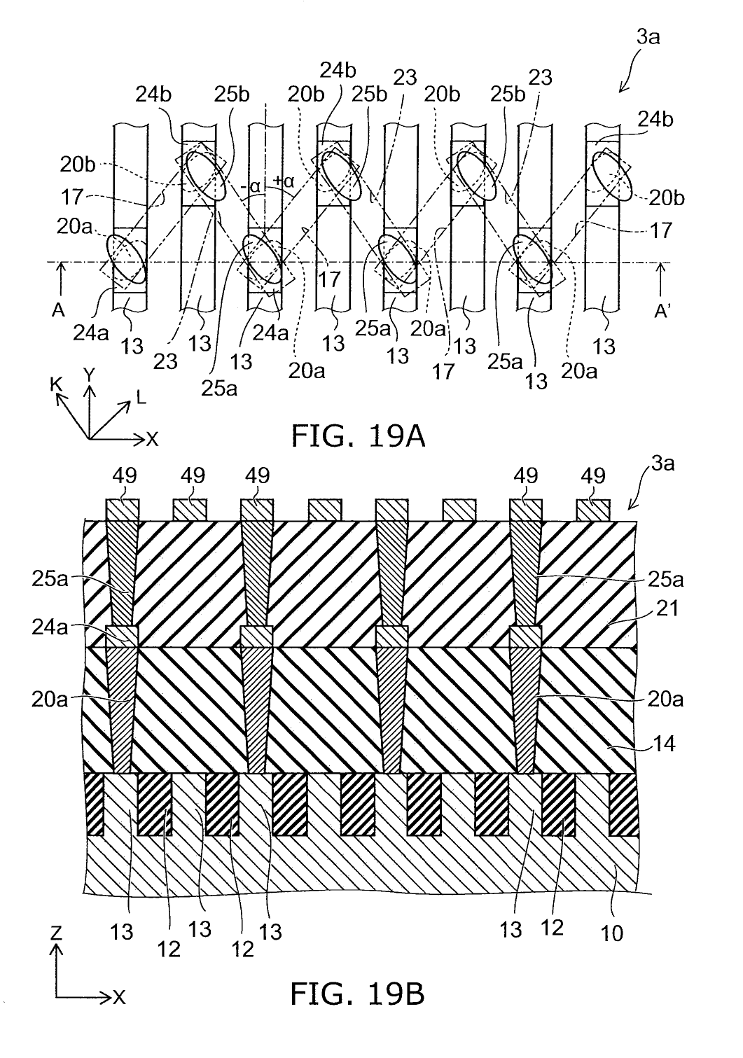

FIG. 19A is a plan view showing an integrated circuit device according to the modification; and FIG. 19B is a cross-sectional view along line A-A′ shown in FIG. 19A.

As shown in FIG. 19A and FIG. 19B, the integrated circuit device 3a according to the modification differs from the integrated circuit device 3 (referring to FIG. 16A and FIG. 16B) according to the third embodiment described above in that intermediate interconnects 24a and 24b are provided. The intermediate interconnect 24a is interposed between the contact 20a and a via 25a; and the intermediate interconnect 24b is interposed between the contact 20b and a via 25b. When viewed from the Z-direction, the configurations of the intermediate interconnects 24a and 24b are rectangles; the widths of the intermediate interconnects 24a and 24b are about the same as the width of the active area 13; and the lengths of the intermediate interconnects 24a and 24b are enough to overlap the contacts 20a and 20b by considering the alignment shift. Also, the intermediate interconnects 24a and 24b are arranged in a staggered configuration as viewed from the Z-direction. The configurations of the intermediate interconnects 24a and 24b may be trapezoidal configurations as viewed from the Z-direction and may be trapezoidal configurations as viewed from the X-direction and the Y-direction. Also, the intermediate interconnects 24a and 24b may be provided at the same height as the source line (not shown). Also, the intermediate interconnects 24a and 24b may not be provided.

Otherwise, the manufacturing method, the configuration, and the effects of the modification are similar to those of the third embodiment described above.

### Fourth Embodiment

A fourth embodiment will now be described.

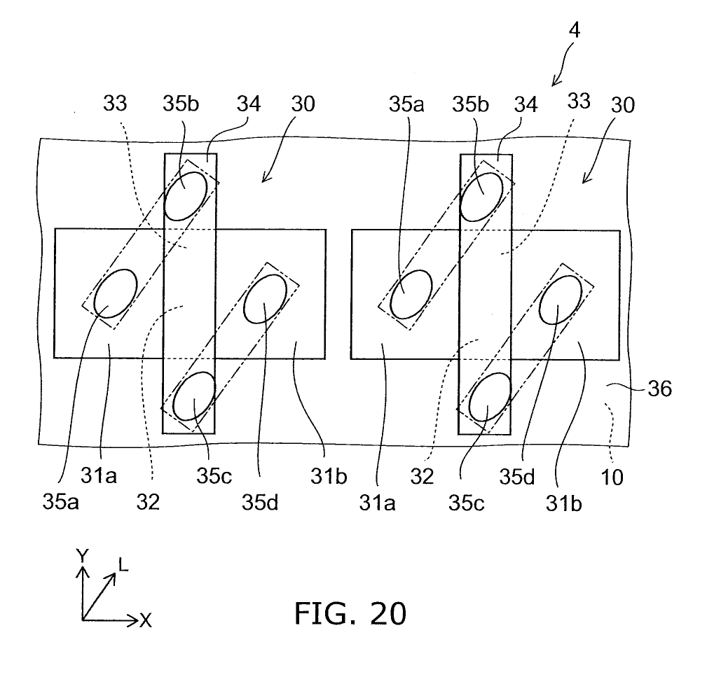

FIG. 20 is a plan view showing an integrated circuit device according to the embodiment.

The embodiment is an example in which contacts such as those of the first embodiment described above are provided sense amplifier region in addition to the memory cell region of NAND flash memory.

FIG. 20 shows the sense amplifier region of the NAND flash memory.

In the integrated circuit device 4 according to the embodiment as shown in FIG. 20, a pair of source/drain regions 31a and 31b are formed in the upper layer portion of the silicon substrate 10. The pair of source/drain regions 31a and 31b are separated from each other in, for example, the X-direction. The region between the pair of source/drain regions 31a and 31b is used as a channel region 32. An element-separating insulating film 36 is provided on the silicon substrate 10 around the pair of source/drain regions 31a and 31b and around the body region made of the channel region 32 between the pair of source/drain regions 31a and 31b.

A gate insulator film 33 is provided on the silicon substrate 10 in the region directly above the channel region 32. The gate insulator film 33 may be provided in the region directly above the source/drain regions 31a and 31b in addition to the region directly above the channel region 32. A gate electrode 34 is provided on the gate insulator film 33. The gate electrode 34 is disposed in the region directly above the channel region 32 and extends from the region directly above the channel region 32 toward two Y-direction sides.

A field effect transistor 30 is formed of the source/drain regions 31a and 31b, the channel region 32, the gate insulator film 33, and the gate electrode 34. Multiple transistors 30 are arranged in a matrix configuration along the X-direction and the Y-direction in the sense amplifier region of the integrated circuit device 4. The multiple transistors 30 are partitioned from each other by the element-separating insulating film 36.

Also, a contact 35a is provided in a portion of the region directly above the source/drain region 31a. The lower end of the contact 35a is connected to the source/drain region 31a. A contact 35b is provided in a portion of the region directly above the gate electrode 34. The contact 35b is disposed at the portion of the gate electrode 34 extending in the Y-direction from the region directly above the channel region 32, that is, in the region directly above the element-separating insulating film 36. The lower end of the contact 35b is connected to a portion of the gate electrode 34. Similarly to the contacts 20a and 20b of the first embodiment described above, the contacts 35a and 35b are formed inside one opening 17 made in the resist film 16 (referring to FIG. 3A). Accordingly, the contact 35b is positioned in the L-direction as viewed from the contact 35a Also, the configurations of the contacts 35a and 35b are configurations having longitudinal directions in the L-direction as viewed from the Z-direction.

Also, a contact 35c is provided at one other portion of the region directly above the gate electrode 34. The contact 35c is disposed at the portion of the gate electrode 34 extending in the Y-direction from the region directly above the channel region 32, that is, in the region directly above the element-separating insulating rim 36. The lower end of the contact 35c is connected to the one other portion of the gate electrode 34. A contact 35d is provided at a portion of the region directly above the source/drain region 31b. The lower end of the contact 35d is connected to the source/drain region 31b. The contacts 35c and 35d are formed inside one opening 17 made in the resist film 16. Accordingly, the contact 35d is positioned in the L-direction as viewed from the contact 35c. Also, the configurations of the contacts 35c and 35d are configurations having longitudinal directions in the L-direction as viewed from the Z-direction.

Effects of the embodiment will now be described.

According to the embodiment, in the sense amplifier region as well, the arrangement density of the contacts 35a to 35d can be increased. Thereby, the arrangement period and diameter of the interconnects connected to the contacts 35a to 35d can be about the same as the arrangement period and diameter of the bit lines provided in the memory cell region. As a result, higher integration of the sense amplifier region can be realized.

Otherwise, the manufacturing method, the configuration, and the effects of the embodiment are similar to those of the first embodiment described above. For example, the configurations of the contacts formed in the memory cell region of the integrated circuit device 4 are similar to the configurations of the contacts 20a and 20b of the integrated circuit device 1 shown in FIG. 6.

Although an example is illustrated in the embodiment in which the method for forming two contacts inside one opening 17 described above is applied to the memory cell region and the sense amplifier region of NAND flash memory, this is not limited thereto and is applicable to, for example, a peripheral circuit region of NAND flash memory. Also, applications are possible in integrated circuit devices other than NAND flash memory.

According to the embodiments described above, an integrated circuit device and a method for manufacturing the integrated circuit device having high integration can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An integrated circuit device, comprising:
a first conductive member extending in a first direction;
a second conductive member extending in the first direction;
a first contact having a lower end connected to the first conductive member; and
a second contact having a lower end connected to the second conductive member,
a position of the first contact in the first direction being different from a position of the second contact in the first direction,
cross sections of the first contact and the second contact having longitudinal directions in a second direction as viewed from above, the second direction being from the first contact toward the second contact.

2. The integrated circuit device according to claim 1, wherein the cross section of the first contact and the cross section of the second contact are ellipses as viewed from above.

3. The integrated circuit device according to claim 1, wherein the cross section of the first contact as viewed from above is a water drop shape having a sharp end on second contact side, and the cross section of the second contact as viewed from above is a water drop shape having a sharp end on first contact side.

4. The integrated circuit device according to claim 1, further comprising:
a third conductive member disposed in the same layer as the first conductive member and the second conductive member, the third conductive member extending in the first direction;
a third contact having a lower end connected to the third conductive member;
a first via having a lower end connected to en upper end of the second contact; and
a second via having a lower end connected to an upper end of the third contact,
a position of the third contact in the first direction being different from a position of the second contact in the first direction,
cross sections of the first via and the second via having longitudinal directions in a third direction as viewed from above, the third direction being from the first via toward the second via.

5. The integrated circuit device according to claim 4, further comprising:
a first intermediate interconnect provided between the second contact and the first via; and
a second intermediate interconnect provided between he third contact and the second via.

6. The integrated circuit device according to claim 1, wherein the first conductive member and the second conductive member are mutually-partitioned in an upper layer of a semiconductor substrate.

7. The integrated circuit device according to claim 6, further comprising:
a pair of source/drain regions formed in the upper layer of the semiconductor substrate;
a gate electrode provided above a region between the pair of source/drain regions;
a third contact having a lower end connected to one selected from the source/drain regions;
a fourth contact having a lower end connected to the gate electrode;
a fifth contact having a lower end connected to the gate electrode; and
a sixth contact having a lower end connected to the other selected from the source/drain regions,
a direction from the third contact toward the fourth contact being the second direction,
a direction from the fifth contact toward the sixth contact being the second direction,
cross sections of the third contact, the fourth contact, the fifth contact, and the sixth contact having longitudinal directions in the second direction as viewed from above.

8. The integrated circuit device according to claim 7, further comprising an element-separating insulating film surrounding an active area including the pair of source/drain regions and the region between the pair of source/drain regions, the fourth contact and the fifth contact being disposed above the element-separating insulating film.

9. An integrated circuit device, comprising:
a plurality of conductive members extending in a first direction, the plurality of conductive members being arranged periodically in a second direction orthogonal to the first direction; and
a plurality of contacts having lower ends connected respectively to the conductive members,
wherein a second distance is different from a first distance when the plurality of contacts is divided into a plurality of pairs including two contacts adjacent to each other, the first distance is a distance in the second direction between two of the contacts belonging to a same pair, the second distance is a distance in the second direction between two of the contacts adjacent to each other in the second direction and belonging to different pair.

10. The integrated circuit device according to claim 9, wherein one contact selected from each pair is positioned at a first position in the first direction, and the other contact is positioned at a second position in the first direction, the second position being different from the first position.

11. The integrated circuit device according to claim 9, wherein
cross sections of the contacts have longitudinal directions in a third direction as viewed from above, the third direction intersecting both the first direction and the second direction, and
a direction from one contact selected from each pair toward the other contact is the third direction.

12. The integrated circuit device according to claim 11, wherein the cross sections of the contacts are ellipses as viewed from above.

13. The integrated circuit device according to claim 11, wherein the cross section of one of the contacts is a water drop shape having a sharp end on side of one other of the contacts as viewed From above.

14. A method for manufacturing an integrated circuit device, comprising:
forming a first conductive member and a second conductive member extending in a first direction, the first conductive member and the second conductive member being separated from each other in a second direction being orthogonal to the first direction;
forming an insulating film on the first conductive member and the second conductive member;
forming a resist film on the insulating film;
making an opening in the resist film, a longitudinal direction of the opening being a third direction intersecting both the first direction and the second direction, one end portion of the opening in the longitudinal direction being positioned above the first conductive member, one other end portion of the opening in the longitudinal direction being positioned above the second conductive member;
etching the insulating film using the resist film as a mask to make a first through-hole in the insulating film under the one end portion of the opening and to make a second through-hole in the insulating film under the one other end portion of the opening the first through-hole reaching the first conductive member, the second through-hole reaching the second conductive member; and
filling a conductive material into the first through-hole and into the second through-hole.

15. The method for manufacturing the integrated circuit device according to claim 14, wherein the making of the opening includes:
exposing the resist film by irradiating light from two sides in a direction orthogonal to the third direction; and
developing the resist film.
